(19) United States
(12) Patent Application Publication
(10) Pub. No.: US 2011/0316427 A1
(43) Pub. Date: Dec. 29, 2011

(54) PHOTODIODE, DISPLAY DEVICE PROVIDED WITH PHOTODIODE, AND METHODS FOR MANUFACTURING THE PHOTODIODE AND THE DISPLAY DEVICE

(75) Inventor: Nami Okajima, Osaka (JP)

(73) Assignee: SHARP KABUSHIKI KAISHA, Osaka (JP)

(21) Appl. No.: 13/254,787

(22) PCT Filed: Feb. 3, 2010
(86) PCT No.: PCT/JP2010/000627

§ 371 Date: Sep. 2, 2011

(30) Foreign Application Priority Data
Mar. 3, 2009 (JP) 2009-049655

(51) Int. Cl. H05B 37/02; H01L 31/18; H01L 31/102

(52) U.S. Cl. 315/151; 257/458; 438/83; 257/E31.061

(57) ABSTRACT

A photodiode (10) according to the present invention is provided with a p-type semiconductor region (11), an i-type semiconductor region (12) and an n-type semiconductor region (13). A protection film (9) provided on the surface of the photodiode has been removed from at least a light receiving portion of the photodiode (10). Accordingly, the present invention provides the photodiode (10) that has less changes in its characteristics even with the prolonged use and a display device that uses the photodiode (10).

### TECHNICAL FIELD

The present invention relates to a photodiode, a display device provided with the photodiode and methods of manufacturing the photodiode and the display device.

### BACKGROUND ART

Liquid crystal display devices are used in a variety of devices. As the devices installed with liquid crystal display devices become increasingly diversified, the usage environment of liquid crystal display devices widens, which creates a demand for the comfortable operability in various environments as well as a strong need for less power consumption. Additionally, liquid crystal display devices themselves are having an increasing range of functions, and the increase of the functions further widens the field of application of liquid crystal display devices.

Patent Document 1 discloses a liquid crystal display device capable of capturing images as an example of an effort for the multi-functionality. The display device disclosed in Patent Document 1 is a display device having an optical sensor capable of capturing images mounted on an image element array substrate constituting the liquid crystal display device.

This display device provided with the image capturing feature has an optical sensor capable of capturing images directly mounted on an image element array substrate constituting the liquid crystal display device and performs image capturing by changing the amount of electric charge of a capacitor connected to the optical sensor in accordance with the amount of light received at the optical sensor and detecting the voltage across the capacitor.

This optical sensor is constituted by a photodiode, for example, and can be easily formed in each pixel because this photodiode can be simultaneously formed in a step of forming an active element such as a TFT for driving a pixel electrode of the display device.

Additionally, in a liquid crystal display device, because the visibility is largely affected by an environment in which the liquid crystal display device is used, especially ambient light (outside light), the display luminance is adjusted in accordance with ambient light of a place where it is used. For this reason, display devices are installed with an optical sensor for detecting ambient light, and in a liquid crystal display device, by utilizing a step of forming TFTs and the like, a photodiode as an optical sensor can be easily formed on an active element substrate where TFTs and the like are formed in the same step.

FIG. 4 shows an example of incorporating an optical sensor in a liquid crystal display device. In FIG. 4, 40 is a liquid crystal panel and has a substrate 41 where a plurality of active elements such as a TFT is formed, and an opposite substrate 42. On the substrate 41, a plurality of pixel electrodes formed by a transparent conductive film and a plurality of active elements for driving the pixel electrodes, for example, Thin Film Transistors (TFTs) and the like, are provided, and the plurality of pixel electrodes and the like are arranged in a matrix, forming a display region. On the opposite substrate 42, although not shown in FIG. 4, an opposite electrode and a color filter are provided. The opposite substrate 42 is placed so as to overlap the display region of the substrate 41.

Additionally, on the substrate 41, in regions around the display region, data drivers 43 and gate drivers 44 are formed, and the active elements provided in the display region are connected to the data drivers and the gate drivers through not-shown data wiring and gate wiring, respectively. Further, in the regions around the display region of the substrate 41, a plurality of photodiodes 45 are provided.

FIG. 5 shows a photodiode as an optical sensor used in the display device described above. In FIG. 5, 60 is a photodiode as an optical sensor constituted as a lateral photodiode having a p-type semiconductor region 61, an i-type semiconductor region 62, and an n-type semiconductor region 63. The photodiode 60 is manufactured from a silicon film formed on a base coat insulating film 53 on a substrate 51 made of glass and the like, and this silicon film is formed simultaneously with a formation of a silicon film for constituting a TFT and the like formed in the display region.

The p-type semiconductor region 61 and the n-type semiconductor region 63 of the photodiode 60 are connected to source wiring films 58, 58 through wiring 57, 57 in contact holes provided in a gate insulating film 54, an interlayer insulating film 55, and a planarizing layer 56, and become lead-out terminals to the outside. 59 is a protection film which also has a function as a planarizing layer. 52 is a light shielding layer made of a metal film and the like and is provided when it is desired to shield light from the bottom in FIGS. 5 and 6.

Also, here, the gate insulating film 54 is an insulating layer to insulate a gate electrode of the TFT manufactured simultaneously with the photodiode 60. In FIG. 5, however, the gate electrode is not shown in the figure because it has been removed.

Additionally, in a manner similar to above, the source wiring films 58, 58 are formed by utilizing a conductive film made of metal or the like that is used as source wiring and the like of the TFT manufactured simultaneously with the photodiode 60, and are therefore referred to as source wiring films due to this manufacturing origin.

In FIG. 5, 65 indicates a liquid crystal layer, and 66 indicates an opposite substrate, and an example in which a photodiode is formed in a display region of a liquid crystal display device is shown. In this case, the photodiode may be formed for each pixel.

### RELATED ART DOCUMENTS

### Patent Documents

Patent Document 1: Japanese Patent Application Laid-Open Publication No. 2006-3857 (Publication date: Jan. 5, 2006)

### SUMMARY OF THE INVENTION

### Problems to be Solved by the Invention

In the art shown in FIG. 5 described above, however, it has been found that the output characteristics of the photodiode 60 will change as the display device is used. For this reason, in the conventional photodiode, the apparent amount of light received at the photodiode 60 will be changed, and as a result, stable output cannot be obtained, causing a problem of a lack of reliability.

The present invention was made in view of the above-described problem of the conventional art, and it is an object of the present invention to provide a photodiode that has less changes in output characteristics even with the prolonged use, to provide a display device having the photodiode, to provide a method of manufacturing the photodiode, and to provide a method of manufacturing the display device having the photodiode.

### Means for Solving the Problems

To solve the above-described problem, a photodiode of the present invention includes at least one conductive semiconductor film for junction formation formed on a substrate, an interlayer insulating film formed on the semiconductor film, a wiring film provided on the interlayer insulating film, and a protection film covering the wiring film, wherein the protection film has been removed at least at a light receiving portion of the photodiode.

A photodiode that has less changes in output characteristics even with the prolonged use can be thereby provided.

To solve the above-described problem, a display device of the present invention is characterized in that on the substrate, in addition to the above-mentioned photodiode, a pixel electrode for display and an active element for driving the pixel electrode are formed.

A display device having a photodiode that has less characteristic changes can be thereby obtained.

To solve the above-described problem, a manufacturing method of a photodiode of the present invention is a method to manufacture a photodiode that includes at least one conductive semiconductor film for junction formation formed on a substrate, an interlayer insulating film formed on the semiconductor film, a wiring film provided on the interlayer insulating film, and a protection film covering the wiring film, the method including a step of forming a junction on the substrate, a step of forming an interlayer insulating film on the junction, a step of connecting each region forming the junction to a wiring film, a step of forming a protection film on the wiring film and the interlayer insulating film, and a step of removing the protection film from a portion corresponding to at least a light receiving portion of the photodiode.

A photodiode that has less characteristic changes with a high degree of reliability can be thereby made.

To solve the above-describe problem, another manufacturing method of a photodiode of the present invention is a method to manufacture a photodiode that includes a semiconductor film having a p-type semiconductor region, an i-type semiconductor region and an n-type semiconductor region formed on a substrate in this order along the plane direction of the substrate, an interlayer insulating film formed on the semiconductor film, a wiring film provided on the interlayer insulating film, and a protection film covering the wiring film, the method including a step of forming a silicon film on the substrate, a step of forming a main body of the photodiode by forming a p-type semiconductor region, an i-type semiconductor region, and an n-type semiconductor region on the silicon film, a step of forming an interlayer insulating film on the main body of the photodiode, a step of connecting the p-type semiconductor region and the n-type semiconductor region of the photodiode to the wiring film, a step of forming a protection film on the wiring film and the interlayer insulating film, and a step of removing the protection film from a portion corresponding to at least a light receiving portion of the photodiode.

A photodiode that has less characteristic changes with a high degree of reliability can be thereby made simultaneously with an active element of a display device such as a TFT in the same manufacturing step.

Additional objects, features, and advantages of the present invention will be sufficiently clarified by the description which follows. Also, the benefits of the present invention will become apparent from the explanation hereinafter with reference to the attached figures.

### Effects of the Invention

As described above, a photodiode of the invention of the present application includes at least one conductive semiconductor film for junction formation formed on a substrate, an interlayer insulating film formed on the semiconductor film, a wiring film provided on the interlayer insulating film, and a protection film covering the wiring film, wherein the protection film has been removed at least at a light receiving portion of the photodiode.

Also, a manufacturing method of a photodiode of the invention of the present application is a method to manufacture a photodiode that includes at least one conductive semiconductor film for junction formation formed on a substrate, an interlayer insulating film formed on the semiconductor film, a wiring film provided on the interlayer insulating film, and a protection film covering the wiring film, the method including a step of forming a junction on the substrate, a step of forming an interlayer insulating film on the junction, a step of connecting each region forming the junction to the wiring film, a step of forming a protection film on the wiring film and the interlayer insulating film, and a step of removing the protection film from a portion corresponding to at least a light receiving portion of the photodiode.

This makes it possible to provide a photodiode that has less changes in output characteristics even with the prolonged use. Also, this makes it possible to provide a display device provided with such a photodiode and a manufacturing method thereof.

### BRIEF DESCRIPTION OF THE DRAWINGS

FIG. 1 shows a structure of a photodiode of an embodiment of the present invention.

FIG. 2 shows a manufacturing method of a photodiode of an embodiment of the present invention.

FIG. 3 shows a manufacturing method of a photodiode of an embodiment of the present invention.

FIG. 4 shows a conventional example of a liquid crystal display device with an optical sensor incorporated therein.

FIG. 5 shows a structure of a conventional photodiode.

### DETAILED DESCRIPTION OF EMBODIMENTS

Before embodiments of the present invention are explained, findings of the inventor of the present invention and others that led to the present invention will be described.

As previously described, when a display device having a photodiode of the conventional structure shown in FIG. 5 is used, the output characteristics of the photodiode may change over time. According to research conducted by the inventor and others, it was found that this is due to electric charge being trapped in a protection film (the protection film 59 in FIG. 5) disposed on a front surface of a photodiode as an optical sensor as a display device is used, causing the output characteristics of a light receiving potion to change.

Although there are various possible causes of the entrapment of the electric charge, it appears to be caused by a generation of leak current by ITO bias or bias applied to terminals, resulting in the electric charge to be accumulated.

When the protection film (corresponding to the protection film 59 in FIG. 5) was removed, a photodiode that has less characteristic changes with drastically improved reliability was obtained. The present invention was made based on the above findings of the inventor and others.

Hereinafter, embodiments of the present invention are described. Although various limitations preferable for embodiments of the present invention are added in the description below, the technical scope of the present invention is not limited to the embodiments or the figures hereinafter.

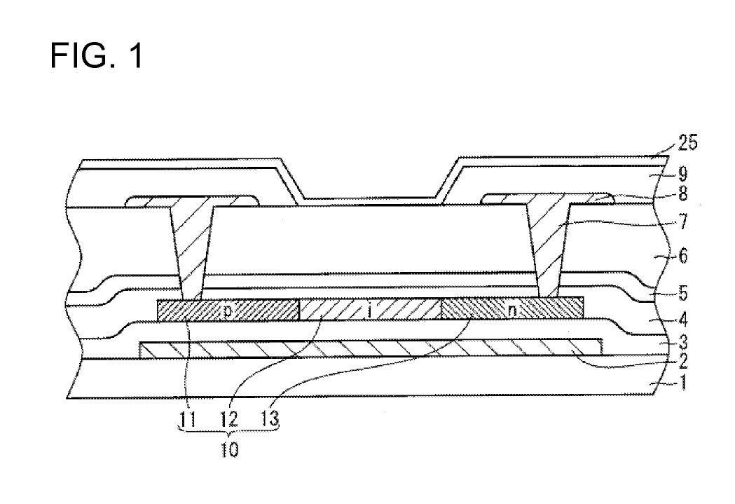

All of the figures are schematically drawn to clarify structures, and therefore, they do not indicate actual dimensional relations. Also, in FIGS. 1 to 3, same numerical references are given to same members. Therefore, in principle, the detailed description of the same members will not be repeated in each figure.

FIG. 1 is a diagram showing a structure of a photodiode according to the present invention, and a structure of the photodiode forming portion is illustrated in a cross-sectional view.

In FIG. 1, 1 is a substrate made of glass and the like, and is the same substrate as a substrate on which TFTs and the like, which are active elements for driving a display device, are formed. The substrate is also referred to as an active matrix substrate. An active element such as a TFT is not shown in FIG. 1. On the substrate 1, a light shielding film 2 is disposed. Although, in the embodiment shown in FIG. 1, the light shielding film 2 is formed in a region where a photodiode described below is formed, this light shielding film 2 is not necessarily required.

3 is a base coat insulating film, and a photodiode 10 is disposed on this base coat insulating film 3. The photodiode 10 has at least one conductive semiconductor film for junction formation. In this embodiment, the photodiode 10 includes a p-type semiconductor region 11, an i-type semiconductor region 12, and an n-type semiconductor region 13, and is configured as a lateral PIN photodiode. The p-type semiconductor region 11, the i-type semiconductor region 12, and the n-type semiconductor region 13 are formed on the substrate 1 in this order along the plane direction of the substrate 1.

The p-type semiconductor region 11 and the n-type semiconductor region 13 of the photodiode 10 are connected to source wiring films 8, 8 through wiring 7, 7 disposed in contact holes formed through a gate insulating film 4, an interlayer insulating film 5, and a planarizing layer 6. The planarizing layer 6 is usually constituted of an insulating material and also has a function as an insulating layer. The source wiring films 8, 8 become lead-out electrodes for driving the photodiode 10.

Here, as explained in the description of the conventional art using FIG. 5, the gate insulating film 4 refers to an insulating film formed simultaneously with a formation of a gate insulating film when an active element such as a TFT is formed. The source wiring film 8 refers to a portion of a wiring layer used as a wiring film, which is formed simultaneously with the formation of a source wiring layer and a drain wiring layer of an active element such as a TFT, and for convenience, it is described as a source wiring film, omitting the fact that it is also a formation of a drain wiring layer. On the source wiring film 8, a protection film 9 that also functions as a planarizing layer is provided.

As shown in FIG. 1, the protection film 9 has been removed above a portion that becomes a light receiving portion of the photodiode, and a large recess is thereby created. Although it is preferable that the region from which the protection film 9 is removed be at least a portion corresponding to the i-type semiconductor region 12 of the photodiode 10, which is a light receiving portion of the diode, a small offset, of course, is acceptable. Limiting the removed portion of the protection film to a portion that becomes a light receiving portion of the photodiode in this manner has a beneficial effect of keeping the removed portion of the protection film to a minimum, and thereby eliminating adverse effect to the planarization of the surface. Additionally, by having an opening near the light receiving portion of the photodiode, small reflection of light is generated from wall surfaces and the like of the opening, resulting in an effect of the enhancement of the light receiving efficiency.

A transparent electrode film 25 is disposed on the protection film 9 including a region on the front surface of the photodiode 10 where the protection film 9 is removed. The transparent electrode film 25 is a transparent electrode film provided when pixel electrodes of a display device are formed and is made of ITO or IZO.

According to the photodiode 10 of the structure shown in FIG. 1, because it does not have an insulating layer (protection film 9) itself that traps electric charge as a display device is used, there will be no characteristic changes caused by the entrapment of electric charge in the photodiode 10 as an optical sensor.

Also, even when the transparent electrode film 25 is not provided, because there is no insulating layer (protection film 9) that causes the entrapment of electric charge, the characteristic changes of the photodiode 10 can be suppressed. However, the even better result can be expected when the transparent electrode film 25 is provided.

That is, because the same voltage as the voltage applied to pixel will be applied to the transparent electrode film 25, the transparent electrode film 25 will be maintained at a constant voltage. When a transparent electrode is not provided, if there is electric charge trapped in the top surface of the upper portion of the light receiving layer, the diode characteristics will change over time because of the change in capacitance between the top surface and the i-type semiconductor region (12) that forms a light receiving layer, which includes the gate insulating film 4, the interlayer insulating film 5, and the planarizing layer 6. By providing the transparent electrode film 25 over a light receiving portion, however, capacitance generated in the gate insulating film 4, the interlayer insulating film 5, and the planarizing layer 6 can be maintained constant and more stable diode characteristics can be thereby obtained.

The photodiode 10 may be used for detection of ambient light of a display device so as to adjust the brightness of the display device itself in accordance with the brightness of the ambient light. This makes it possible to provide the optimal viewing whether indoors or outdoors because the ambient light in which the display device is used is detected, and in accordance with the brightness thereof, the display brightness of the display device itself is adjusted. Also, because unnecessarily bright display can be avoided, the energy consumption can be reduced.

Additionally, the photodiode 10 may be provided outside of a display region of a display device. In this manner, because the ambient light in which a display device is used can be detected at a spot that is, although outside of a display region, very close to the display region, in a manner similar to above, the display brightness of a display device itself is displayed in accordance with the brightness of the ambient light, and the optimal viewing can be made possible whether indoors or outdoors. Also, because unnecessarily bright display can be avoided, the energy consumption can be reduced. In this case, there is no need to form a photodiode in a display region, therefore, the density of display elements in the display region can be enhanced, and also the aperture ratio as a display device can be improved as well.

Additionally, the photodiode 10 may be configured adjacent to each pixel in a display region of a display device to obtain a display device provided with a photodiode that can be used for image capturing or for a touch panel. With this structure, image capturing can be done by a plurality of photodiodes that have less characteristic changes with a high degree of reliability, and thereby, the high quality image capturing can be provided over a long period of time. Also, when it is used as a touch panel, because the stable detection of a finger or the like can be performed, a high quality touch panel capable of responding to complex movements and the like can be configured.

The photodiode may also be formed for each pixel adjacent to each pixel, or one photodiode may be formed for a plurality of pixels. Further, the photodiode may be formed in a certain region only, such as, for example, forming only display pixels in the upper half of a display device and forming a photodiode adjacent to each pixel in the lower half. It is apparent that one photodiode may be formed for a plurality of pixels in this case too.

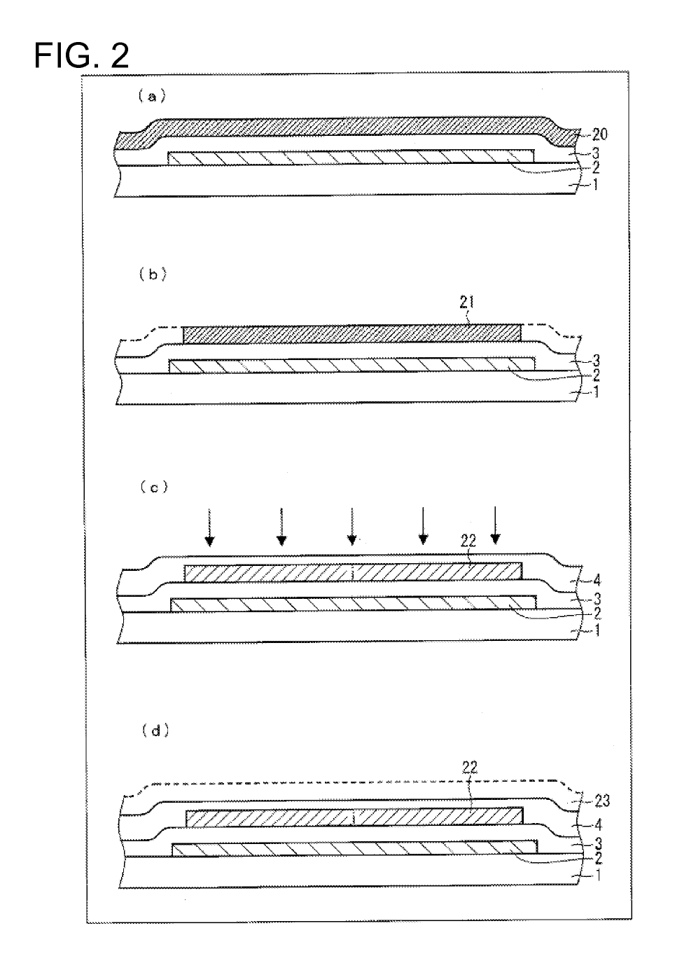

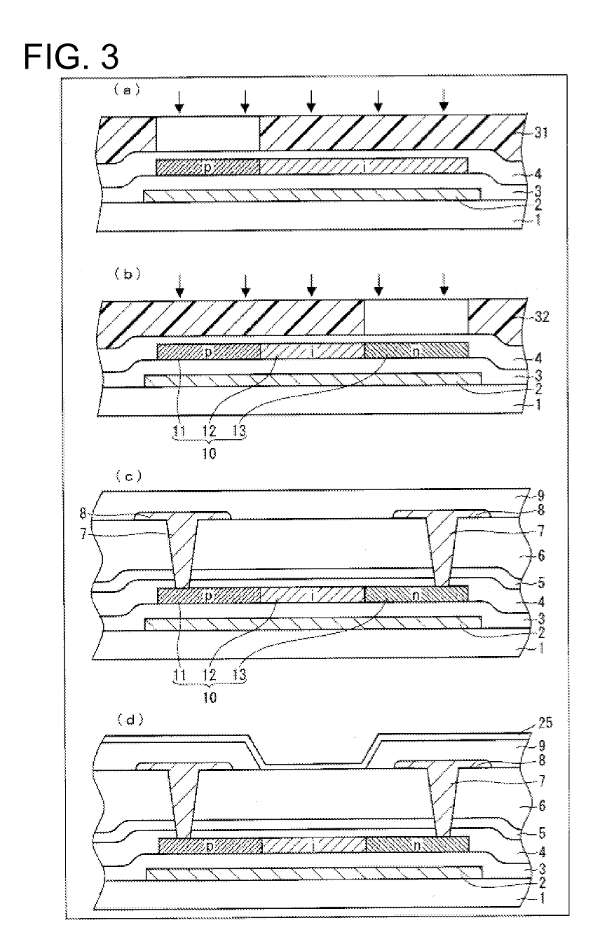

FIGS. 2 and 3 are diagrams showing a manufacturing method of a photodiode described using FIG. 1 according to the present invention. Although FIGS. 2 and 3 particularly show the photodiode portion only, a display device provided with active elements such as TFTs can be manufactured simultaneously, and for convenience, a manufacturing method for a display device provided with a photodiode will be explained as well.

Also, in FIGS. 1, 2 and 3, because the same numerical references are given to the same members, detailed explanations for the same members are not repeated.

In FIG. 2(a), 1 is a substrate made of glass and the like and is the same substrate as a glass substrate on which an active element such as a TFT is formed in a not-shown display region. Usually, in the display region, a plurality of active elements are formed in a matrix, and therefore, this substrate may be also referred to as an active matrix substrate.

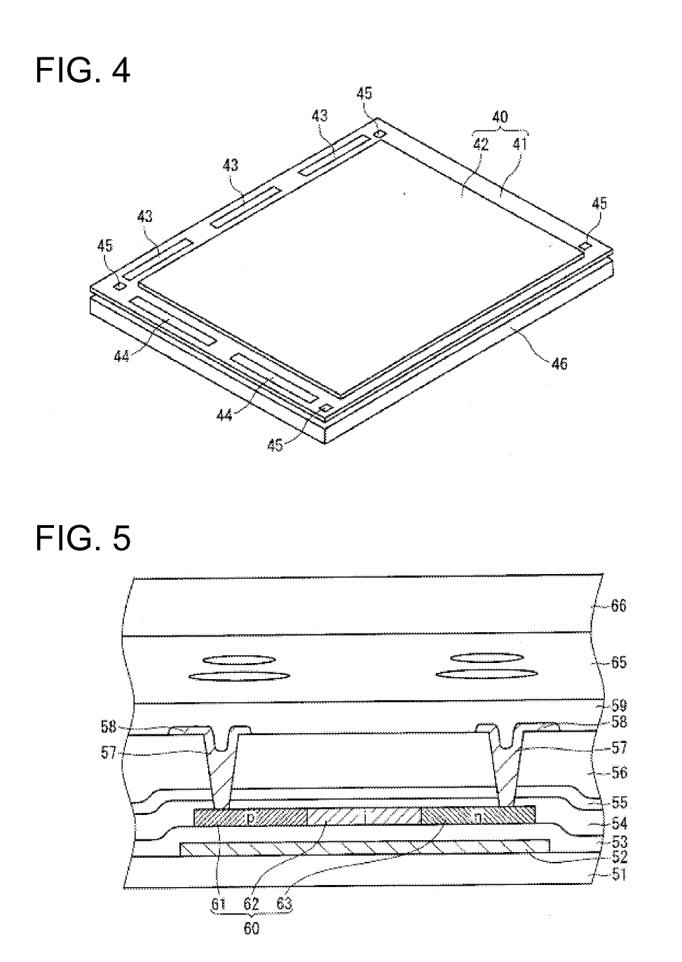

First, on one surface of the glass substrate 1 that becomes a base, an insulator made of Si or the like or a metal film made primarily of an element, such as Ta, Ti, W, Mo, or Al, which will become a light shielding film, is formed by a CVD (chemical vapor disposition) method, a sputtering method, or the like. The acceptable film thickness is 50 nm or more, for example. Next, a resist pattern is formed using photolithography in a portion that overlaps a formation region of a light shielding film on a silicon film used for a photodiode. Thereafter, the insulating film or the metal film is etched using the resist pattern as a mask to obtain a light shielding film 2. This light shielding film 2 needs to be provided when a back light and the like is placed below FIG. 2, but is not necessarily required in an application such as shown in FIG. 4, for example.

Thereafter, a base coat insulating film 3 is formed so as to cover the light shielding film 2. The base coat insulating film 3 can be formed by forming a silicon oxide film or a silicon nitride film using the CVD method, for example. Also, the base coat insulating film 3 may be either single-layered or multiple-layered. The thickness is set in a range of about 100 nm to 500 nm, for example.

Further, on the base coat insulating film 3, a silicon film 20 that becomes a photodiode is formed by the CVD method or the like. The silicon film 20 is made of continuous grain silicon or low temperature polysilicon. The low temperature polysilicon film is formed by the following steps, for example. First, a silicon oxide film and an amorphous silicon film are formed on the base coat insulating film 3 in this order. Next, laser annealing is performed to the amorphous silicon film to promote the crystallization. The silicon film 20 formed of low temperature polysilicon is thereby obtained.

In this embodiment, the silicon film 20 made of low temperature polysilicon is also used as a silicon film that constitutes a TFT as an active element (not shown in the figure). That is, the formation of the above described silicon film 20 can be performed using a formation step of a silicon film that constitutes a TFT.

Next, patterning of the silicon film 20 is performed. FIG. 2(b) shows this situation. That is, a resist pattern is formed in a portion that overlaps a photodiode forming portion of the silicon film 20, and using this resist pattern as a mask, etching is performed. A patterned silicon film 21 is thereby obtained as shown in FIG. 2(b).

Next, a gate insulating film 4 that becomes an interlayer insulating film is formed on the patterned silicon film 21. FIG. 2(c) shows this situation. The reason of this naming “gate insulating film 4” is that this gate insulating film 4 is formed utilizing a formation step of a gate insulating film that constitutes a TFT. Similar to the base coat insulating film 3, the gate insulating film 4 may be a silicon oxide film or a silicon nitride film formed by the CVD method or the like, and may be either single layered or multiple-layered. Specifically, if a silicon oxide film is formed, the plasma CVD method may be performed using SiH4 and N2O (or N2O2) as a source gas. The thickness of the gate insulating film 4 is set in a range of about 10 nm to 120 nm.

Next, in order to adjust dosage of the patterned silicon film 21, ion implantation is performed using impurities of p-type such as boron (B) or indium (In), and setting the implantation energy in a range of 10 keV to 80 KeV, and the dosage in a range of 5×10¹⁴ (ion) to 2×10¹⁶ (ion), for example. It is preferable to set the impurity concentration after implantation to be in a range of 1.5×10²⁰ to 3×10²¹ (atom/cm³) approximately. In this manner, a silicon film 22, which has been patterned and whose dosage has been adjusted, can be obtained as shown in FIG. 2(c).

Next, as shown in FIG. 2(d), a gate electrode film 23 is formed on the silicon film 22. In a region where a TFT is formed, this gate electrode film 23 is etched into a predetermined shape to become a gate electrode, but in a region where a photodiode is formed, it is removed in the etching for the gate electrode formation. In FIG. 2(d), the gate electrode film 23 is indicated in dashed lines to show this situation. The gate electrode film 23 is formed using a single element of Ta, Ti, W, Mo, Al or the like, or a metallic material made primarily of an above-mentioned element by sputtering or vacuum evaporation, for example.

FIGS. 3(a) and 3(b) are diagrams for explaining steps of performing requisite ion implantations to the patterned silicon film 22, which has been adjusted in dosage, in order to form the p-type semiconductor region 11 and the n-type semiconductor region 13, thereby forming the photodiode 10 of PiN configuration.

FIG. 3(a) is a diagram for explaining a step of performing ion implantation to form a diffusion layer of p-type. First, a resist pattern 31 is formed on the gate insulating film 4 using a photolithography technique. The resist pattern 31 has an opening in a portion that overlaps the p-type semiconductor region 11 of the photodiode 10, which will be created eventually. Next, ion implantation is performed using p-type impurities, such as boron (B) or indium (In), with the implantation energy in a range of 10 keV to 80 KeV and the dosage in a range of 5×10¹⁴ (ion) to 2×10¹⁶ (ion), for example. It is preferable that the impurity concentration after implantation be in a range of 1.5×10²⁰ to 3×10²¹ (atom/cm³) approximately. After the ion implantation, the resist pattern 31 is removed.

Next, ion implantation is performed to form a diffusion layer of n-type. FIG. 3(b) is a diagram for explaining this step. Although FIG. 3(b) only shows a photodiode forming portion, in this embodiment, the n-type diffusion layers are formed simultaneously for a photodiode for an optical sensor and for a TFT for driving a pixel electrode. Specifically, first, a resist pattern 32 is formed. The resist pattern has openings in a portion that overlaps an n-layer forming region of the photodiode, and in a portion that overlaps a source region and a drain region of the TFT for driving pixel electrode, although not shown in the figure. Next, ion implantation is performed using n-type impurities, such as phosphate (P) or arsenic (As), with the implantation energy in a range of 10 keV to 100 KeV and the dosage in a range of 5×10¹⁴ (ion) to 1×10¹⁶ (ion), for example. At this time as well, it is preferable that the impurity concentration after implantation be in a range of 1.5×10²° to 3×10²¹ (atom/cm³) approximately.

When this ion implantation is finished, the photodiode 10 having the p-type semiconductor region 11, the i-type semiconductor region 12, and the n-type semiconductor region 13 is formed as shown in FIG. 3(b). After the ion implantation is completed, the resist pattern 32 is removed. By the steps described above, the structure portion of the PiN photodiode 10 is formed, and at the same time, a p-type TFT and an N-type TFT are formed.

Next, as shown in FIG. 3(c), the interlayer insulating film 5, the planarizing layer 6, and the like are formed, and in these interlayer insulating film 5 and planarizing layer 6, contact holes for drawing electrodes from the p-type semiconductor region 11 and the n-type semiconductor region 13 are further formed. When a silicon oxide film is used as the interlayer insulating film 5, the plasma CVD method may be performed using SiH4 and N2O (or O2) as a source gas, for example. Additionally, the contact holes are formed by creating a resist pattern using a photolithography technique and by etching the contact hole portion using this resist pattern as a mask.

Wiring 7 is formed in the contact holes, and necessary etching is performed to a source wiring layer on the photodiode 10 formed simultaneously with a formation of a source wiring layer in a TFT region to form the source wiring films 8, 8. Specifically, first, a conductive layer is formed using a single element of tantalum (Ta), titanium (Ti), tungsten (W), molybdenum (Mo), aluminum (Al) or the like, or a metallic material made primarily of an aforementioned element by sputtering or vacuum evaporation. Next, a resist pattern of a desired shape is formed by photolithography, and using this resist pattern as a mask, the conductive layer is etched. Further, as shown in FIG. 3(c), on the patterned wiring layer 8 and the planarizing layer 6, a protection film 9, which also functions as a planarizing layer that planarizes the top of a pixel, is formed.

In the protection film 9, an opening needs to be formed to electrically connect a pixel electrode, which will be formed later, to a TFT for driving the pixel electrode. At the same time of forming this opening, the protection film 9 in a region above the photodiode 10 is removed to form an opening as shown in FIG. 3(d). Then, a transparent electrode film 25 is formed. The transparent electrode film 25 is also formed in a pixel electrode forming region. Photolithography, etching, and the like are used to dispose the transparent electrode film 25 at the designated portions. The transparent electrode film is formed of ITO, IZO, or the like and is disposed in design portions through.

A photodiode that has less changes in its characteristics can be thereby obtained. Therefore, when a liquid crystal panel module with a touch panel incorporating such an optical sensor is made, for example, reliability of the optical sensor is ensured.

Although the above explanation has been made using an example of a photodiode of PiN configuration, the similar effect can be expected with not only the photodiode of PiN configuration, but also other configurations (such as PI Schottky, for example).

As described above, although the figures in the above description specifically show the photodiode areas only, it is apparent that the optical sensor can be manufactured simultaneously with the manufacturing process for a TFT and the like as an active element in a display region, and a photodiode can also be formed for each pixel.

Also, the present invention is not limited to each embodiment described above. Various modifications of the present invention may be made by those skilled in the art within the scope defined by the claims. That is, additional embodiments can be obtained by combining technical means which are appropriately modified without departing from the scope defined by the claims.

To solve the above-mentioned problem, another photodiode according to the present invention is characterized in that the photodiode is formed by a semiconductor film having a p-type semiconductor region, an i-type semiconductor region, and an n-type semiconductor region formed on a substrate in this order along the plane direction of the substrate.

This makes it possible to provide a PIN type photodiode having a p-type semiconductor region, an i-type semiconductor region and an n-type semiconductor region, which has less changes in output characteristics even with the prolonged use.

To solve the above-mentioned problem, another photodiode according to the present invention is characterized in that a transparent electrode film is formed on the protection film.

This makes it possible to provide a photodiode with more stable characteristics because the same voltage signal as that applied to a pixel can be sent onto the transparent electrode film, and therefore, the transparent electrode film can be maintained at a constant voltage.

To solve the above-mentioned problem, another photodiode according to the present invention is characterized in that a light receiving portion of the photodiode where the protection film is not provided is a portion corresponding to the i-type semiconductor region of the photodiode.

This leads to the effect of eliminating adverse effect to the planarization of the surface because the removed portion of the protection film can be kept to a minimum. Additionally, in this case, because an opening is provided adjacent to the light receiving portion of the photodiode, small reflection of light is generated from wall surfaces of the opening, resulting in another effect of the enhancement of light receiving efficiency.

To solve the above-mentioned problem, another display device according to the present invention is characterized in that the active element is a TFT, and the wiring film is a wiring film that is formed when source wiring of the TFT is formed.

This makes it possible to form a photodiode in the same process as a formation process of an active element, resulting in the effect of very easy manufacturing.

To solve the above-mentioned problem, another display device according to the present invention is characterized in that the photodiode detects ambient light of the display device, and the brightness of the display device is adjusted in accordance with the brightness of the ambient light.

This makes it possible to provide the optimal viewing whether indoors or outdoors because the display brightness of the display device itself can be adjusted in accordance with the ambient light in which the display device is used. Also, this makes it possible to avoid the display device being unnecessarily bright and thereby contributes to the reduction of energy consumption.

To solve the above-mentioned problem, a display device according to the present invention is characterized in that the photodiode is formed adjacent to a pixel in a display region and is used for image capturing or for a touch panel.

This makes it possible to install photodiodes over a wide area, and therefore, a display device that can capture images or can be used as a touch panel can be obtained.

The specific embodiments or examples described in the section of “Detailed Description Of Embodiments” are solely intended to clarify the technical aspects of the present invention, and shall not be interpreted narrowly to be limited to such specific embodiments, and accordingly, various modification may be made without departing from the spirit of the present invention as well as the scope defined by the claims below.

### INDUSTRIAL APPLICABILITY

According to the present invention, a photodiode that has less changes in its characteristics even with the prolonged use can be obtained. Also, a display device provided with such a photodiode as an optical sensor that has less changes in its characteristics, which can be used as a touch panel, can be obtained. Applications of the display device are not limited to liquid crystal display devices, but include various display devices such as EL display devices. Because the display devices provided with such a photodiode are used in many fields, the industrial applicability is very high.

### DESCRIPTION OF REFERENCE CHARACTERS

1 substrate
2 light shielding film
3 base coat insulating film
4 gate insulating film
5 interlayer insulating film
6 planarizing layer
7 wiring
8 source wiring film
9 protection film/planarizing film
10 photodiode
11 p-type semiconductor region
12 i-type semiconductor region
13 n-type semiconductor region
20 semiconductor layer
21 patterned semiconductor layer
22 patterned semiconductor layer with adjusted dosage
25 pixel electrode film
31, 32 resist patterns

1. A photodiode comprising:
at least one conductive semiconductor film for junction formation formed on a substrate;
an interlayer insulating film formed on the semiconductor film;
a wiring film provided on the interlayer insulating film; and
a protection film covering the wiring film, wherein the protection film is removed at least at a light receiving portion of the photodiode.

2. The photodiode according to claim 1, wherein the photodiode is formed of a semiconductor film including a p-type semiconductor region, an i-type semiconductor region and an n-type semiconductor region disposed on the substrate in this order along a plane direction of said substrate.

3. The photodiode according to claim 1, wherein a transparent electrode film is formed on the protection film.

4. The photodiode according to claim 1, wherein the light-receiving portion of the photodiode where the protection film is not provided is a portion corresponding to an i-type semiconductor region of the photodiode.

5. A display device, comprising a photodiode, a pixel electrode for display, an active element for driving the pixel electrode on a substrate,
wherein said photodiode is the photodiode according to claim 1.

6. The display device according to claim 5, wherein the active element is a TFT, and the wiring film is a wiring film formed simultaneously with a formation of source wiring of the TFT.

7. The display device according to claim 5, wherein the photodiode detects ambient light of the display device, and the brightness of the display device is adjusted in accordance with the brightness of the ambient light.

8. The display device according to claim 5, wherein the photodiode is formed adjacent to the pixel in a display region, and is used for image capturing or for a touch panel.

9. A method of manufacturing a photodiode that comprises at least one conductive semiconductor film for junction formation formed on a substrate, an interlayer insulating film formed on the semiconductor film, wiring films provided on the interlayer insulating film, and a protection film covering the wiring films, the method comprising;
forming a junction on the substrate;
forming an interlayer insulating film on the junction;
connecting respective regions forming the junction to the wiring films, respectively;
forming a protection film on the wiring films and on the interlayer insulating film; and
removing the protection film from a portion corresponding to at least a light receiving portion of the photodiode.

10. The method of manufacturing a photodiode according to claim 9, wherein the photodiode is a PIN type photodiode that includes a p-type semiconductor region, an i-type semiconductor region and an n-type semiconductor region, the method comprising;
forming a silicon film on the substrate;
forming a main body of the photodiode by forming a p-type semiconductor region, an i-type semiconductor region and an n-type semiconductor region on the silicon film;
forming an interlayer insulating film on the main body of the photodiode;
connecting the p-type semiconductor region and the n-type semiconductor region of the photodiode to the wiring films, respectively;
forming a protection film on the wiring films and the interlayer insulating film; and
removing the protection film from a portion corresponding to at least a light receiving portion of the photodiode.
